(19) United States
(12) Patent Application Publication
(10) Pub. No.: US 2011/0133286 A1
(43) Pub. Date: Jun. 9, 2011

(54) INTEGRIERTER SCHALTUNGSTEIL

(76) Inventor: Franz DIETZ, Untereisesheim (DE)

(21) Appl. No.: 12/960,257

(22) Filed: Dec. 3, 2010

Related U.S. Application Data
(60) Provisional application No. 61/266,434, filed on Dec. 3, 2009.

(51) Int. Cl. H01L 29/78

(52) U.S. Cl. 257/368; 257/E29.255

(57) ABSTRACT

An integrated circuit part containing at least one MOS transistor with a trace system, with a source region having a source contact, and with a drain region having a drain contact, and with a gate region having a gate contact, and with a first cover layer lying on the gate, source, and drain regions and a first trace level formed thereupon, and with a second cover layer, lying above the first trace level, with a second trace level lying thereupon, and with a trace formed and connected with the source contact, and with a trace formed and connected with the drain contact, whereby a first metal region, arranged at least partially between the trace, connected to the source contact, and the trace, connected to the drain contact, is provided above the gate region lying on the first cover layer and/or the second cover layer, and the metal region is connected neither to the drain contact nor to the source contact or to the gate contact.

The present invention relates to an integrated circuit part, according to the preamble of claim 1.

Integrated circuit parts are used as components in the manufacture of integrated circuits. Integrated circuit parts consist preferably of a component, especially a semiconductor component and generally several overlying trace levels for connecting the circuit parts to one another. Typical semiconductor components are, for example, MOS transistors, which are connected to other components by means of at least two-level metallization. If a high dielectric strength of the circuit parts is expected, DMOS transistors are used preferably as high-blocking semiconductor components. Transistors of this type have between the source and drain regions a drift region, which has a field plate formed over parts of the drift region and simultaneously formed as a gate. Further, the DMOS transistors can be made preferably as large-area driver structures. In addition to the high blocking voltages which are applied between the drain and source and are preferably within the range above 10 V, most preferably above 50 V, drain currents flow in the range up to a few amperes.

Unexamined German Pat. App. No. DE 103 42 996 A1 discloses an integrated circuit arrangement with a multilevel metallization. Because of the use of soft dielectric cover layers, so-called electrically insulated dummy structures, which consist of layer stacks of metal areas, are provided arbitrarily distributed for stabilizing the metallization levels.

U.S. Pat. App. No. US 2008/0265339 A1 discloses a MOS transistor with capacitor structures, formed of metal and lying on the gate region of the transistor within the overlying dielectric layers, for forming large filter structures with the greatest capacitance possible within a range above several 100 pF.

Tests by the applicant have shown that defects in the trace system can lead to failures in the integrated circuits, particularly in integrated circuit parts that have flat DMOS-based driver structures. In this case, it became evident that an important failure cause is the occurrence of short circuits in the trace system. Short-circuits are especially frequent between the traces, connected to the source contacts, and traces, connected to the drain contacts. The occurrence of short circuits in driver structures is promoted, inter alia, by defects such as gaps and cracks in the trace system cover layers lying above the semiconductor layers, and by the ductility of the metal used for the traces, as well as high voltages and high currents.

The object of the invention is to improve an integrated circuit part as much as possible.

The object is achieved by an integrated circuit part with the features of claim 1. Advantageous embodiments of the invention are the subject of dependent claims and included in the description.

According to the subject of the invention, an integrated circuit part is provided, containing at least one MOS transistor, preferably a DMOS transistor, with a trace system, with a source region having a source contact, and with a drain region having a drain contact, and with a gate region having a gate contact, and with a first cover layer lying on the gate, source, and drain regions and a first trace level formed thereupon, and with a second cover layer, lying above the first trace level, with a second trace level lying thereupon, and with a trace formed and connected with the source contact, and with a trace formed and connected with the drain contact, whereby a first metal region, arranged at least partially between the trace, connected to the source contact, and the trace, connected to the drain contact, is provided above the gate region lying on the first cover layer and/or the second cover layer, and the metal region is connected neither to the drain contact nor to the source contact or to the gate contact.

An advantage of the present invention is that the reliability of the integrated circuit part is increased by the insertion of one or more metal regions not connected to the terminals of a transistor. As a result, the lifetime in particular of the entire integrated circuit is substantially increased. Evidently, a metal region, lying at least partially between the source and drain traces, represents a barrier to the formation of short circuits between the drain and source terminal. Tests by the applicant have shown that the formation of intermediate metal regions on the first cover layer, i.e., within the first trace level, or above the first cover layer, i.e., in another trace level, does not affect the electrical transistor properties. Further, the metal regions can also be formed within the additional cover layers lying on the first cover layer. As the terminal of the gate in a MOS or DMOS transistor is de facto currentless and supplied only with a low voltage, preferably below 10 V, at most preferably below 6 V, it is sufficient to form the gate terminal as a minimal contact and to shift it sideways relative to the drain and source contacts, preferably in the first trace level.

In a refinement, an intermediate metal region is provided on each cover layer, which has a trace connected to the source contact and a trace connected to the drain contact. According to another refinement, no intermediate metal region is formed on the topmost cover layer, which has a trace connected to the source contact and a trace connected to the drain contact. Especially in integrated circuit parts, which have a plurality of trace levels, the reliability is increased especially greatly when, starting in the first level, an intermediate metal region is formed in all of the levels.

According to a preferred embodiment, the trace assigned to the same source region of a MOS transistor or a DMOS transistor in different trace levels and the trace, assigned to the same drain region of a MOS transistor or a DMOS transistor, and the intermediate metal regions in the respective trace level are preferably arranged in part, most preferably completely one above the other in the vertical respect, i.e., stack-like.

According to a preferred refinement, the metal regions formed in different trace levels are connected electrically to one another by means of one or more vias. Tests by the applicant have shown that the individual metal regions need not be connected to a reference potential, therefore can float or be clamped to a reference potential.

In another embodiment, several intermediate metal regions, lying next to one another, are arranged within a trace level between a trace, connected to the source contact, and a trace, connected to the drain contact. The metal regions can be connected in the vertical direction with overlying intermediate metal region by means of vias. In this case, metal regions arranged next to one another and preferably separated spatially can be connected in an electrically different manner and can have a different potential; i.e., while a metal region is clamped to a predefined potential, the neighboring metal region floats.

In a preferred refinement, the metal regions are formed in the form of strips as traces lying on a cover layer. As a result, the space requirement by the metal areas is especially low.

According to an alternative embodiment, the metal region(s) can be formed at least partially by means of individual cylindrical columns, whereby the columns with the exception of the first cover layer cut through at least one other cover layer. In this case, it is preferable to produce the metal columns by via etching and preferably to allow the vias to end with the bottom side of a metal area. Further, it is preferable to use the metal connection of the traces of the respective trace as the metal for the metal area in the individual trace levels, whereas hard metals, particularly tungsten, are used to form the vias.

According to a preferred embodiment, the metal region or metal regions can also be produced by means of trench etching, which occurs after the formation of the trace system, and filling by means of a tungsten deposition process occurs after this. The depth of the trench etching is preferably adjusted in such a way that it ends above or on the first cover layer. Care must be taken here that the aspect ratio of the trench is adjusted such that a void-free filling preferably with a hard metal can occur.

The invention will be described in greater detail below with reference to the drawings. In this case, functionally equivalent circuit parts are provided with the same reference characters. In the drawing,

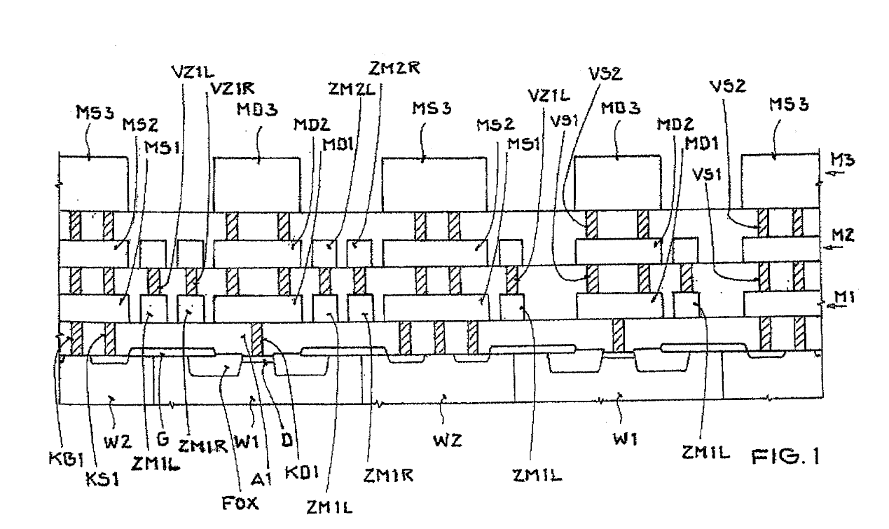

FIG. 1 shows a schematic cross-sectional view of an integrated circuit part with a multilevel metallization with intermediate metal areas in the trace levels;

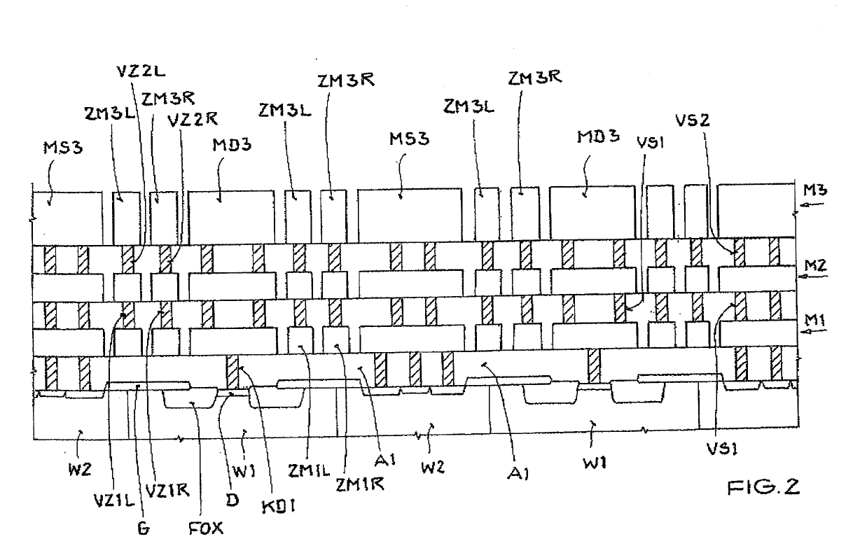

FIG. 2 shows a schematic cross-sectional view of an integrated circuit part with a multilevel metallization with intermediate metal areas;

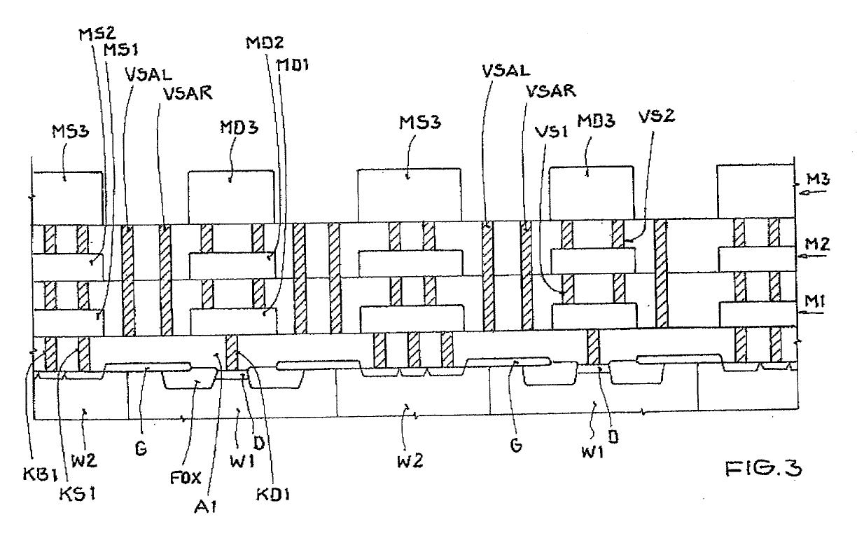

FIG. 3 shows a schematic cross-sectional view of an integrated circuit part with a multilevel metallization with intermediate metal areas;

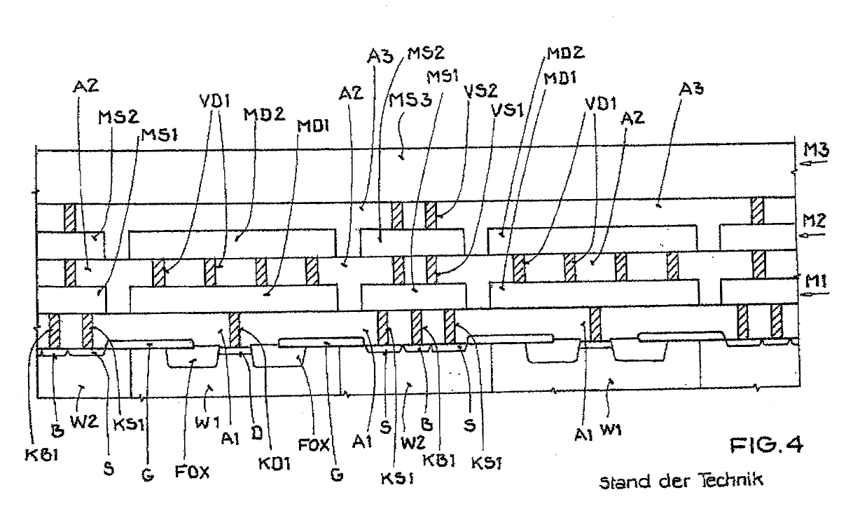

FIG. 4 shows a schematic cross-sectional view of an integrated circuit part according to the state of the art with a multilevel metallization without intermediate metal areas.

In the illustration of FIG. 4, an integrated circuit part according to the prior art is shown, having a schematic cross-sectional view of a DMOS driver structure with a plurality of first well regions W1, with a plurality of drain regions D, with a plurality of second well regions W2, with a plurality of source regions S and a plurality of body regions B, and a plurality of field regions FOX, and a plurality of gate regions G. The drain, source, body, and gate regions D, S, B, and G are covered with a first cover layer A1. The drain regions D are each connected through the first cover layer A1, by means of a drain contact KD1, the source regions by means of a source contact KS1, and the gate regions by means of a contact (not shown). The specific contacts in this case are made in the shape of columns. A first trace level M1, having a plurality of individual traces MD1, connected to drain contacts KD1, and a plurality of individual traces MS1, connected to the source and body contacts KD1 or KS1, respectively, is formed on the first cover layer A1.

The trace level M1 or the first cover layer A1 is covered with a second cover layer A2. The individual traces MD1 are connected through the second cover layer A2 in each case by means of a plurality of vias VD1, and the individual traces MS1 in each case by a plurality of vias MS1 to traces MD2, which are formed within the second trace levels M2 and are assigned to drain regions D, or to traces MS2, which are assigned to source regions S.

A third cover layer A3 is formed on the second cover layer A2 or on the traces MD2 or MS2. A trace MS3, formed flat in a third trace level M3 and assigned to the source regions, is connected through the third cover layer A3 in each case by means of a plurality of vias VD2 to the underlying traces MS2 also assigned to the source regions. Although in the present illustration of FIG. 4, a flat metal cover layer MS3 is shown in the third trace level M3, it can also be divided into individual subregions. In the present embodiment, the source regions and the body regions of the DMOS transistor are connected to one another by means of the first trace level.

An embodiment of the invention of an integrated circuit part is shown in FIG. 1. Only the differences to the explanations provided in relation to the FIG. 4 will be set forth below. A first metal region ZM1L and in places a second metal region ZM1R are arranged in the first trace level M1 between trace levels MS1, assigned to source regions S, and trace levels MD1, assigned to drain regions D. Further, the first metal regions ZM1L and the second metal regions, if present, are each arranged on the first cover layer A1 over gate regions G of the driver structure. Third metal regions ZM2L and fourth metal regions ZM2R are formed on the second cover layer A2, i.e., in the second trace level M2; each of these is arranged between trace levels MS2, connected to source regions S, and trace levels MD2, connected to drain regions D. The third metal regions ZM2L and the fourth metal regions ZM2R are connected by means of vias VZ1 or VZ2 to the first metal regions ZM1L and second metal regions ZM1R.

In contrast to the prior art disclosed in FIG. 4, individual trace levels MS3, spatially separated from one another, are formed on the second cover layer A2, i.e., in trace level M3; each of these is connected by means of vias VS2 to the underlying trace levels MS2. Further, trace levels MD3, which are assigned to the drain regions or connected electrically to the respective drain regions, are formed on the second cover layer A2. In contrast to trace level M2, no intermediate metal areas are formed in trace level M3. Accordingly, the spaces between trace levels MS3 and trace levels MD3 are not filled. In the embodiment of FIG. 1, the trace levels and the metal areas in the specific trace levels M1, M2, and M3 are shown equally wide, but the dimensions of the trace levels can also be made different.

Another embodiment of the invention of an integrated circuit part is shown in FIG. 2. Only the differences to the explanations provided in relation to FIG. 2 and FIG. 4 will be set forth below. A fifth metal region ZM3L and a sixth metal region ZM1R are arranged in each case in the third trace level M3, i.e., lying on the second cover layer A2, between trace levels MS3, assigned to source regions S, and trace levels MD3, assigned to drain regions D.

Another embodiment of the invention of an integrated circuit part is shown in FIG. 3. Only the differences to the explanations provided in relation to the previous figures will be set forth below. No intermediate metal areas are formed in the individual trace levels M1, M2, and M3. Further, cover layers A2 and A3 between the trace levels, assigned to source regions S, and the trace levels, assigned to the drain regions, preferably as part of via etching, are drilled through or separated in the form of columns, and either columnar or vertical plate-like seventh metal regions VSAL and in places eighth metal regions VSAR are formed preferably by means of a via filling process.

Tests by the applicant have shown that the intermediate metal areas arranged within the respective trace levels are preferably to be connected to a reference potential, particularly to a ground potential. Failures caused by faults in the metal system are largely suppressed by the integrated circuit parts of the invention, particularly in DMOS driver structures. Further, it is sufficient to provide at least one metal region between the respective source and drain trace levels and to make the metal region if necessary in the shape of columns and/or also as a vertical plate. The shown embodiments of the intermediate metal regions can also be combined together in a single MOS structure and applied to metal systems with a substantially greater number of trace levels. Preferably, the metal regions of the individual trace levels are to be arranged in stack form directly one above the other.

The metal areas formed as intermediate areas, particularly in large MOS structures, which are preferably formed as drift MOS driver structures, reduce failures due to short circuits in the metal system of the integrated circuit. According to a refinement, it is advantageous to make the intermediate metal areas connectable or clampable to a reference potential by means of a switch. As a result, the intermediate metal areas can be tested. It is noted that the switch is to be made preferably as a MOS transistor. For a test, a potential is applied to the intermediate metal areas or they are clamped to a potential and a current flow particularly to the adjacent traces is determined. Provided a current flow is detected, conclusions can be drawn about a defect in the trace system.

1. An integrated circuit part containing at least one MOS transistor with a trace system,
with a source region having a source contact,
with a drain region having a drain contact,
with a gate region having a gate contact,
with a first cover layer lying on the gate, source, and drain regions and a first trace level formed thereupon,
with a second cover layer, lying above the first trace level, with a second trace level lying thereupon,
with a trace formed and connected with the source contact, and
with a trace formed and connected with the drain contact, wherein
a first metal region, arranged at least partially between the trace, connected to the source contact, and the trace, connected to the drain contact, as a barrier to the formation of short circuits [page 3, line 10] is provided above the gate region of the MOS transistor lying on the first cover layer and/or the second cover layer, and the metal region is connected neither to the drain contact nor to the source contact or to the gate contact and the metal region either floats or is clamped to a reference potential.

2. The integrated circuit part according to claim 1, wherein an intermediate metal region is provided on each cover layer, which has a trace connected to the source contact and a trace connected to the drain contact.

3. The integrated circuit part according to claim 1, wherein no intermediate metal region is formed on the topmost cover layer, which has a trace connected to the source contact and a trace connected to the drain contact.

4. The integrated circuit part according to claim 1, wherein the traces assigned to the same source region in different trace levels, and the trace levels, assigned to the same drain region, and the intermediate metal regions are arranged at least in part one above the other.

5. The integrated circuit part according to claim 1, wherein metal regions, formed in different trace levels, are connected electrically to one another preferably by means of one or more vias.

6. (canceled)

7. The integrated circuit part according to claim 1, wherein a plurality of intermediate metal regions are provided between a trace connected to the source contact, and a trace connected to the drain contact.

8. The integrated circuit part according to claim 1, wherein in a plurality of intermediate metal regions, which are within a trace level and are adjacent, have a different potential.

9. The integrated circuit part according to claim 1, wherein the metal region is formed in the form of strips as a trace lying on a cover layer.

10. The integrated circuit part according to claim 1, wherein the metal region is formed of individual cylindrical columns and the columns with the exception of the first cover layer cut through at least one additional cover layer.

11. The integrated circuit part according to claim 1, wherein the metal region is formed as a metallic wall, which with the exception of the first cover layer cuts through at least one additional cover layer.

12. The integrated circuit part according to claim 1, wherein a switch is provided, with which it is possible to clamp the metal regions to a reference potential.
